(19) United States
(12) Patent Application Publication
(10) Pub. No.: US 2019/0348999 A1
(43) Pub. Date: Nov. 14, 2019

(54) METHOD AND APPARATUS FOR COMPRESSION AND DECOMPRESSION OF A NUMERICAL FILE

(71) Applicant: Redpine Signals, Inc., San Jose, CA (US)

(72) Inventors: Chandrajit PAL, Khandi (IN); Sunil PANKAJ, Khandi (IN); Wasim AKRAM, Khandi (IN); Amit ACHARYYA, Khandi (IN); Govardhan MATTELA, Hyderabad (IN)

(73) Assignee: Redpine Signals, Inc., San Jose, CA (US)

(21) Appl. No.: 15/978,095

(22) Filed: May 12, 2018

(51) Int. Cl. H03M 7/40

(52) U.S. Cl. CPC H03M 7/4012; H03M 7/4093; H03M 7/4062; H03M 7/405

(57) ABSTRACT

The present invention relates to a method and apparatus for compression and decompression of a numerical file. The compression method comprises: read a numerical file, convert each numerical element into a 32-bit floating point number; combine all the numbers to form a binary numerical file; group the binary numerical file into a n-bit sequence pattern; generate a Huffman tree based on frequency of occurrences of a plurality of unique bit patterns present in the binary numerical file; generate codewords and replace unique bit patterns with codewords so that a compressed binary numerical file is generated. A method for decompression comprises: read a compressed binary numerical file having codewords; fetch a part or entire compressed binary numerical file using an address dictionary; replace the codewords with unique bit patterns using a Huffman tree such that a decompressed binary numerical file being generated.

### FIELD OF THE INVENTION

The present invention relates generally to data compression and decompression. In particular, the invention relates to a method and apparatus for compression and decompression of a numerical file.

### BACKGROUND OF THE INVENTION

To keep a pace with the increasing size of data and complexity for training neural nets, they (the nets) are made deeper to maintain the increasing accuracy of computer vision applications. However, this increases the number of parameters of the neural net model, which in turn expands its operational footprint. This increase in size has several disadvantages from the point of view of its portability in various applications from automobile industry, defense, telecom etc. Compressing a neural net is therefore necessary from the point of view of efficient distributed training, easy embedded platform development and model upgradation by exporting to the client over network etc.

Compression of a Deep Neural Network by network-rearchitecting is commonly applied followed by an encoding technique like Huffman. Huffman compression is generally applied on text files where characters/symbols in it are coded into codewords by computing its frequency of occurrences through a Huffman tree. Designers have applied Huffman coding on numeric data in quantized form, as in the example of Deep Compression technology (as mentioned in the paper namely Song Han, Huizi Mao, and William J Dally. Deep compression: Compressing deep neural network with pruning, trained quantization and Huffman coding. arXiv preprint arXiv:1510.00149, 2015.) where authors have applied compression on the already processed quantized weights of fully connected layer of AlexNet. Weight quantization affects accuracy due to approximation errors. Compression after quantization, occurs within some known range of quantized numbers like the symbols/characters of a text file. Further, In the paper “Compression of Deep Neural Networks for Image Instance Retrieval” (V. Chandrasekhar et. al,), Huffman compression is applied as a part of the compression technologies and tested compression performance on every layer of the neural net model with varying bit patterns at multiple layers. The compression rate varies from 15 to 22% approximately. Therefore, it is evident that none of the existing technologies disclose the method of applying compression directly on unprocessed raw weights of a neural net. To achieve the objective, the conventional Huffman coding is modified with a vision to apply directly on unprocessed network weights.

Researchers till date have commonly used Huffman compression on the quantized network weights, easy I/O burst data transfer where sparsity and repetition of the weights are common in the existing technology. One of the papers (i.e. Evangelia Sitaridi, Massively-Parallel Lossless Data Decompression, 45^{th} International Conference on Parallel Processing (ICPP) 2016, IEEE DOI:10.1109/ICPP.2016.35) tried with Huffman coding scheme while developing a smart technology called Gompresso within compression framework for massively parallel decompression using GPUs. However, they utilized the compression separately on multiple blocks with each separate processing thread which would otherwise increase the computational burden.

In order to overcome the problems of the existing technology as stated herein above paragraphs, the present inventors have developed a method and apparatus for compression and decompression of a numerical file to achieve compression of the unprocessed neural net weights (in a single precision binary format) along with a decompression, which is facilitating layer wise and/or blockwise (containing multiple layers) decompression into memory constrained mobile devices.

### OBJECTS OF THE INVENTION

An object of the invention is to provide a method for compression of a numerical file.

Another object of the invention is to provide an apparatus for compression of a numerical file.

Another object of the invention is to provide a method for decompression of a numerical file.

Another object of the invention is to provide an apparatus for decompression of a numerical file.

### SUMMARY OF THE INVENTION

According to first aspect of the invention, there is provided a method of compression, said method comprising: reading a numerical file, wherein the numerical file comprises a plurality of numerical elements; converting each numerical element into a 32-bit single precision floating point number such that a plurality of 32-bit single precision floating point numbers being generated corresponding to the plurality of numerical elements of the numerical file; combining said plurality of 32-bit single precision floating point numbers corresponding to the plurality of numerical elements of the numerical file such that a binary numerical file being generated; grouping the binary numerical file into a n-bit sequence pattern; generating a Huffman tree based on frequency of occurrences of a plurality of unique bit patterns present in the binary numerical file; generating a plurality of codewords corresponding to said plurality of unique bit patterns using said Huffman tree; and replacing said plurality of unique bit patterns present in the binary numerical file with the corresponding plurality of codewords such that a compressed binary numerical file being generated.

With reference to the first aspect, in a first possible implementation manner of the first aspect, a node of the Huffman tree is a unique bit pattern of said plurality of unique bit patterns.

With reference to the first aspect, in a second possible implementation manner of the first aspect, a compression rate of said compressed binary numerical file is based on said n-bit sequence pattern, wherein the n-bit sequence pattern is at least one of: an 8-bit sequence pattern, a 16-bit sequence pattern, a 32-bit sequence pattern or a 64-bit sequence pattern.

According to second aspect of the invention, there is provided a method for decompression, said method comprising: reading a compressed binary numerical file, wherein said compressed binary numerical file comprises a plurality of codewords; fetching a part of the compressed binary numerical file or the compressed binary numerical file using an address dictionary; and replacing the plurality of codewords with a corresponding plurality of unique bit patterns by using a Huffman tree such that a decompressed binary numerical file being generated.

With reference to the second aspect, in a first possible implementation manner of the second aspect, generating an address dictionary, wherein the address dictionary comprises a plurality of addresses corresponding to a plurality of numerical elements of a numerical file.

With reference to the second aspect, in a second possible implementation manner of the second aspect, said compressed binary numerical file is generated by replacing said plurality of unique bit patterns present in a binary numerical file with the corresponding plurality of codewords.

With reference to the second aspect, in a third possible implementation manner of the second aspect, said Huffman tree is generated based on frequency of occurrences of said plurality of unique bit patterns present in the binary numerical file.

With reference to the second aspect, in a fourth possible implementation manner of the second aspect, a node of the Huffman tree is a unique bit pattern of said plurality of unique bit patterns.

With reference to the second aspect, in a fifth possible implementation manner of the second aspect, the binary numerical file is grouped into a n-bit sequence pattern, wherein the n-bit sequence pattern is at least one of: an 8-bit sequence pattern, a 16-bit sequence pattern, a 32-bit sequence pattern or a 64-bit sequence pattern.

With reference to the second aspect, in a sixth possible implementation manner of the second aspect, the binary numerical file is generated by combining a plurality of 32-bit single precision floating point numbers corresponding to the plurality of numerical elements of the numerical file.

With reference to the second aspect, in a seventh possible implementation manner of the second aspect, a decompression time of said decompressed binary numerical file is based on said n-bit sequence pattern.

According to third aspect of the invention, there is provided an apparatus for compression, the apparatus comprising: a processor; a memory operatively coupled to the processor for executing a plurality of modules present in the memory, the plurality of modules comprising: a read module configured to read a numerical file, wherein the numerical file comprises a plurality of numerical elements; a conversion module configured to convert each numerical element into a 32-bit single precision floating point number such that a plurality of 32-bit single precision floating point numbers being generated corresponding to the plurality of numerical elements of the numerical file; a combination module configured to combine said plurality of 32-bit single precision floating point numbers corresponding to the plurality of numerical elements of the numerical file; a binary numerical file generation module configured to generate a binary numerical file by combining the plurality of 32-bit single precision floating point numbers corresponding to the plurality of numerical elements of the numerical file; a group module configured to group the binary numerical file into a n-bit sequence pattern; a Huffman tree generation module configured to generate a Huffman tree based on frequency of occurrences of a plurality of unique bit patterns present in the binary numerical file; a codeword generation module configured to generate a plurality of codewords corresponding to said plurality of unique bit patterns using said Huffman tree; a replaceable module configured to replace said plurality of unique bit patterns present in the binary numerical file with the corresponding plurality of codewords; and a compressed binary numerical file generation module configured to generate a compressed binary numerical file by replacing said plurality of unique bit patterns present in the binary numerical file with the corresponding plurality of codewords.

With reference to the third aspect, in a first possible implementation manner of the third aspect, a node of the Huffman tree is a unique bit pattern of said plurality of unique bit patterns.

With reference to the third aspect, in a second possible implementation manner of the third aspect, a compression rate of said compressed binary numerical file is based on said n-bit sequence pattern, wherein the n-bit sequence pattern is at least one of: an 8-bit sequence pattern, a 16-bit sequence pattern, a 32-bit sequence pattern or a 64-bit sequence pattern.

According to fourth aspect of the invention, there is provided an apparatus for decompression, the apparatus comprising: a processor; a memory operatively coupled to the processor for executing a plurality of modules present in the memory, the plurality of modules comprising: a read module configured to read a compressed binary numerical file, wherein the compressed binary numerical file comprises a plurality of codewords; a fetch module configured to fetch a part of the compressed binary numerical file or the compressed binary numerical file using an address dictionary; a replaceable module configured to replace the plurality of codewords with a corresponding plurality of unique bit patterns by using a Huffman tree; and a decompressed binary numerical file generation module configured to generate a decompressed binary numerical file by replacing the plurality of codewords with the corresponding plurality of unique bit patterns by using the Huffman tree.

With reference to the fourth aspect, in a first possible implementation manner of the fourth aspect, an address dictionary module is configured to generate an address dictionary, wherein the address dictionary comprises a plurality of addresses corresponding to a plurality of numerical elements of a numerical file.

With reference to the fourth aspect, in a second possible implementation manner of the fourth aspect, a compressed binary numerical file generation module is configured to generate the compressed binary numerical file by replacing the plurality of unique bit patterns present in a binary numerical file with the corresponding plurality of codewords.

With reference to the fourth aspect, in a third possible implementation manner of the fourth aspect, a Huffman tree generation module is configured to generate the Huffman tree based on frequency of occurrences of the plurality of unique bit patterns present in the binary numerical file.

With reference to the fourth aspect, in a fourth possible implementation manner of the fourth aspect, a node of the Huffman tree is a unique bit pattern of the plurality of unique bit patterns.

With reference to the fourth aspect, in a fifth possible implementation manner of the fourth aspect, the binary numerical file is grouped into a n-bit sequence pattern, wherein the n-bit sequence pattern is at least one of: an 8-bit sequence pattern, a 16-bit sequence pattern, a 32-bit sequence pattern or a 64-bit sequence pattern.

With reference to the fourth aspect, in a sixth possible implementation manner of the fourth aspect, a binary numerical file generation module is configured to generate a binary numerical file by combining a plurality of 32-bit single precision floating point numbers corresponding to the plurality of numerical elements of the numerical file.

With reference to the fourth aspect, in a seventh possible implementation manner of the fourth aspect, a decompression time of the decompressed binary numerical file is based on the n-bit sequence pattern.

### BRIEF DESCRIPTION OF THE DRAWINGS

Features, aspects, and advantages of the present invention will be better understood when the following detailed description is read with reference to the accompanying drawings in which like characters represent like parts throughout the drawings, wherein:

FIG. 1 illustrates a flowchart of a method for compression of a numerical file, in accordance with an embodiment of the present invention;

FIG. 2 illustrates a block diagram of an apparatus for compression of a numerical file, in accordance with an embodiment of the present invention;

FIG. 3 illustrates a flowchart of a method for decompression of a numerical file, in accordance with an embodiment of the present invention;

FIG. 4 illustrates a block diagram of an apparatus for decompression of a numerical file, in accordance with an embodiment of the present invention;

FIG. 5 illustrates a block diagram of a generalized computer network arrangement, in accordance with an embodiment of the present invention;

FIG. 6 illustrates a block diagram of a compression technique applied in neural networks; and

FIG. 7 illustrates a block diagram of a decompression technique applied in neural networks.

It should be understood that the drawings are an aid to understanding certain aspects of the present invention and are not to be construed as limiting.

### DETAILED DESCRIPTION OF THE INVENTION

While system and method are described herein by way of example and embodiments, those skilled in the art recognize that a method and apparatus for compression and decompression of a numerical file are not limited to the embodiments or drawings described. It should be understood that the drawings and description are not intended to be limiting to the particular form disclosed. Rather, the intention is to cover all modifications, equivalents and alternatives falling within the spirit and scope of the appended claims. Any headings used herein are for organizational purposes only and are not meant to limit the scope of the description or the claims. As used herein, the word “may” is used in a permissive sense (i.e., meaning having the potential to) rather than the mandatory sense (i.e., meaning must). Similarly, the words “include”, “including”, and “includes” mean including, but not limited to.

The following description is full and informative description of the best method and system presently contemplated for carrying out the present invention which is known to the inventors at the time of filing the patent application. Of course, many modifications and adaptations will be apparent to those skilled in the relevant arts in view of the following description in view of the accompanying drawings and the appended claims. While the system and method described herein are provided with a certain degree of specificity, the present technique may be implemented with either greater or lesser specificity, depending on the needs of the user. Further, some of the features of the present technique may be used to advantage without the corresponding use of other features described in the following paragraphs. As such, the present description should be considered as merely illustrative of the principles of the present technique and not in limitation thereof, since the present technique is defined solely by the claims.

As a preliminary matter, the definition of the term “or” for the purpose of the following discussion and the appended claims is intended to be an inclusive “or” That is, the term “or” is not intended to differentiate between two mutually exclusive alternatives. Rather, the term “or” when employed as a conjunction between two elements is defined as including one element by itself, the other element itself, and combinations and permutations of the elements. For example, a discussion or recitation employing the terminology “A” or “B” includes: “A” by itself, “B” by itself and any combination thereof, such as “AB” and/or “BA.” It is worth noting that the present discussion relates to exemplary embodiments, and the appended claims should not be limited to the embodiments discussed herein.

Disclosed embodiments provide a method and apparatus for compression and decompression of a numerical file.

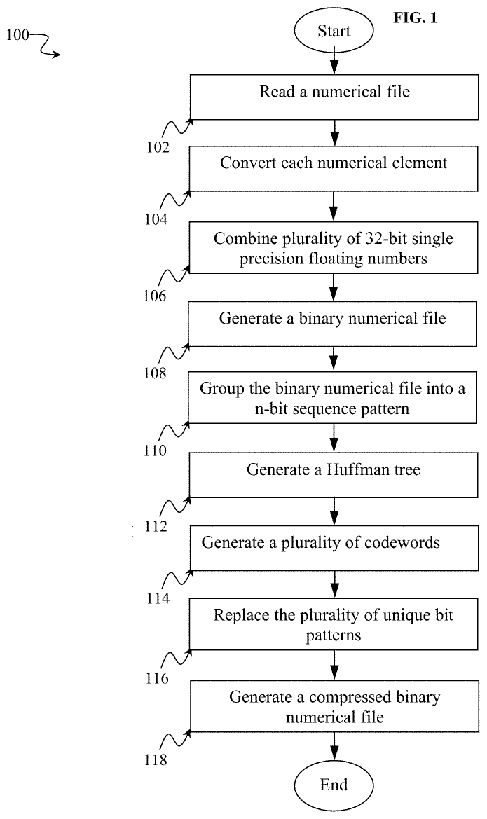

FIG. 1 illustrates a flowchart of a method 100 for compression of a numerical file, in accordance with an embodiment of the present invention. At step 102, read a numerical file. The numerical file comprises a plurality of numerical elements. At step 104, convert each numerical element into a 32-bit single precision floating point number such that a plurality of 32-bit single precision floating point numbers being generated corresponding to the plurality of numerical elements of the numerical file.

At steps 106 and 108, combine the plurality of 32-bit single precision floating point numbers corresponding to the plurality of numerical elements of the numerical file such that a binary numerical file being generated.

At step 110, group the binary numerical file into a n-bit sequence pattern. The n-bit sequence pattern is an 8-bit sequence pattern or a 16-bit sequence pattern or a 32-bit sequence pattern or a 64-bit sequence pattern.

At step 112, generate a Huffman tree based on frequency of occurrences of a plurality of unique bit patterns present in the binary numerical file. A node of the Huffman tree is a unique bit pattern of said plurality of unique bit patterns. At step 114, generate a plurality of codewords corresponding to said plurality of unique bit patterns using said Huffman tree.

At steps 116 and 118, replace said plurality of unique bit patterns present in the binary numerical file with the corresponding plurality of codewords such that a compressed binary numerical file being generated. A compression rate of said compressed binary numerical file is based on said n-bit sequence pattern.

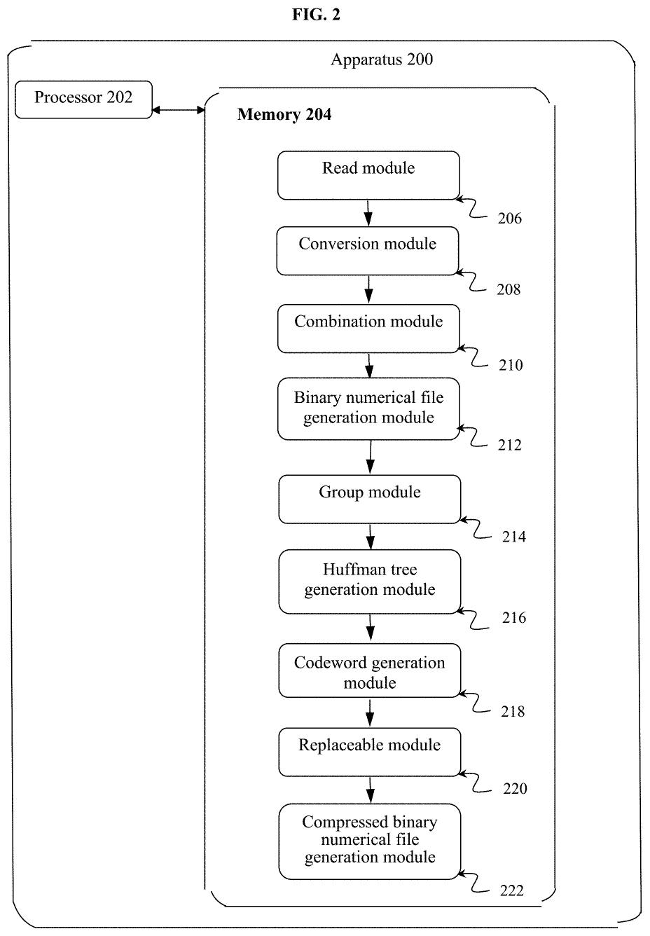

FIG. 2 illustrates a block diagram of an apparatus 200 for compression of a numerical file, in accordance with an embodiment of the present invention. The apparatus 200 for compression comprises a processor 202, a memory 204 operatively coupled to the processor 202 for executing a plurality of modules namely a Read module 206, a Conversion module 208, a Combination module 210, a Binary numerical file generation module 212, a Group module 214, a Huffman tree generation module 216, a Codeword generation module 218, a Replaceable module 220, and a Compressed binary numerical file generation module 222 present in the memory 204.

The plurality of modules namely a Read module 206, a Conversion module 208, a Combination module 210, a Binary numerical file generation module 212, a Group module 214, a Huffman tree generation module 216, a Codeword generation module 218, a Replaceable module 220, and a Compressed binary numerical file generation module 222 are operatively connected to each other.

The read module 206 is configured to read a numerical file, wherein the numerical file comprises a plurality of numerical elements. The conversion module 208 is configured to convert each numerical element into a 32-bit single precision floating point number such that a plurality of 32-bit single precision floating point numbers are generated corresponding to the plurality of numerical elements of the numerical file.

The combination module 210 is configured to combine said plurality of 32-bit single precision floating point numbers corresponding to the plurality of numerical elements of the numerical file. The binary numerical file generation module 212 is configured to generate a binary numerical file by combining the plurality of 32-bit single precision floating point numbers corresponding to the plurality of numerical elements of the numerical file.

The group module 214 is configured to group the binary numerical file into a n-bit sequence pattern. The n-bit sequence pattern is an 8-bit sequence pattern or a 16-bit sequence pattern or a 32-bit sequence pattern or a 64-bit sequence pattern.

The Huffman tree generation module 216 is configured to generate a Huffman tree based on frequency of occurrences of a plurality of unique bit patterns present in the binary numerical file. A node of the Huffman tree is a unique bit pattern of said plurality of unique bit patterns.

The codeword generation module 218 is configured to generate a plurality of codewords corresponding to said plurality of unique bit patterns using said Huffman tree. The replaceable module 220 is configured to replace said plurality of unique bit patterns present in the binary numerical file with the corresponding plurality of codewords.

The compressed binary numerical file generation module 222 is configured to generate a compressed binary numerical file by replacing said plurality of unique bit patterns present in the binary numerical file with the corresponding plurality of codewords. A compression rate of said compressed binary numerical file is based on said n-bit sequence pattern.

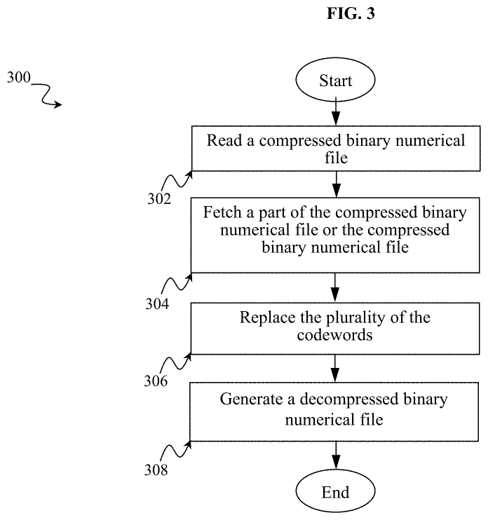

FIG. 3 illustrates a flowchart of a method 300 for decompression of a numerical file, in accordance with an embodiment of the present invention. At step 302, read a compressed binary numerical file, wherein said compressed binary numerical file comprises a plurality of codewords. The said compressed binary numerical file is generated by replacing a plurality of unique bit patterns present in a binary numerical file with the corresponding plurality of codewords.

At step 304, fetch a part of the compressed binary numerical file or the compressed binary numerical file using an address dictionary. The address dictionary comprises a plurality of addresses corresponding to a plurality of numerical elements of a numerical file.

At steps 306 and 308, replace the plurality of codewords with a corresponding plurality of unique bit patterns by using a Huffman tree such that a decompressed binary numerical file being generated. The said Huffman tree is generated based on frequency of occurrences of said plurality of unique bit patterns present in a binary numerical file. A node of the Huffman tree is a unique bit pattern of said plurality of unique bit patterns i.e. each node of the Huffman tree is represented with a unique bit pattern.

The binary numerical file is generated by combining a plurality of 32-bit single precision floating point numbers corresponding to the plurality of numerical elements of the numerical file. After generating the binary numerical file, it is grouped into a n-bit sequence pattern. The n-bit sequence pattern is an 8-bit sequence pattern or a 16-bit sequence pattern or a 32-bit sequence pattern or a 64-bit sequence pattern. A decompression time of said decompressed binary numerical file is based on said n-bit sequence pattern. After decompression, the said decompressed binary numerical file is nothing but the binary numerical file.

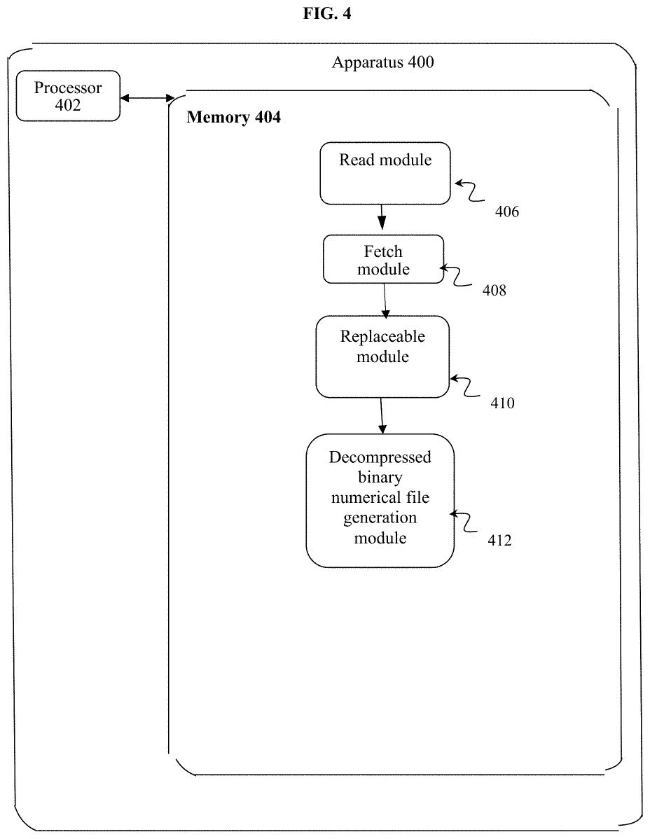

FIG. 4 illustrates a block diagram of an apparatus 400 for decompression of a numerical file, in accordance with an embodiment of the present invention. The apparatus 400 for decompression comprises a processor 402, a memory 404 operatively coupled to the processor 402 for executing a plurality of modules namely a read module 406, a fetch module 408, a replaceable module 410 and a decompressed binary numerical file generation module 412 present in the memory.

The plurality of modules namely a read module 406, a fetch module 408, a replaceable module 410 and a decompressed binary numerical file generation module 412, an address dictionary module, a compressed binary numerical file generation module, a binary numerical file generation module and a Huffman tree generation module are operatively connected to each other.

A read module 406 is configured to read a compressed binary numerical file, wherein said compressed binary numerical file comprises a plurality of codewords. The compressed binary numerical file is generated using a compressed binary numerical file generation module. The said compressed binary numerical file generation module is configured to generate said compressed binary numerical file by replacing said plurality of unique bit patterns present in a binary numerical file with the corresponding plurality of codewords.

A fetch module 408 is configured to fetch a part of the compressed binary numerical file or the compressed binary numerical file using an address dictionary. The apparatus 400 further comprises an address dictionary module, which is configured to generate an address dictionary. The address dictionary comprises a plurality of addresses corresponding to a plurality of numerical elements of a numerical file.

A replaceable module 410 is configured to replace the plurality of codewords with a corresponding plurality of unique bit patterns by using a Huffman tree. The Huffman tree is generated using a Huffman tree generation module. The Huffman tree generation module is configured to generate said Huffman tree based on frequency of occurrences of said plurality of unique bit patterns present in the binary numerical file. A node of the Huffman tree is a unique bit pattern of said plurality of unique bit patterns.

The binary numerical file is generated using a binary numerical file generation module. The binary numerical file generation module is configured to generate a binary numerical file by combining a plurality of 32-bit single precision floating point numbers corresponding to the plurality of numerical elements of the numerical file. After generating the binary numerical file, it is grouped into a n-bit sequence pattern. The said n-bit sequence pattern is an 8-bit sequence pattern or a 16-bit sequence pattern or a 32-bit sequence pattern or a 64-bit sequence pattern.

A decompressed binary numerical file generation module 412 is configured to generate a decompressed binary numerical file by replacing the plurality of codewords with said corresponding plurality of unique bit patterns by using said Huffman tree. A decompression time of said decompressed binary numerical file is based on said n-bit sequence pattern. After decompression, the said decompressed binary numerical file is nothing but the binary numerical file.

An example for explaining Unique bit pattern in the binary numerical file is as follows:

Consider a 2 dimensional array A(i,j) of size m*n. Each entry is a numeric value say A(i,j)=val ---- (1)

Then convert each value val of the said matrix A(i,j) in the equation (1) to its equivalent 32 bit single precision value say vbit, i.e. the way it is stored in memory

i.e val->vbit

A(i,j)=vbit

where each value ‘val’ is represented as a unique pattern of vbit. Therefore, the binary file ‘bfile’, equivalent of the numeric 2D array, is equivalent to n*m number of vbit given as:

(n*m) (vbit)€bfile

The said “bfile” is segmented into n bit patterns where n=8 or 16 or 32 or 64. From such file each such segmented pattern has a unique occurrence. The frequency of occurrences of such unique bit patterns are computed from the entire “bfile” followed by the creation of the Huffman tree.

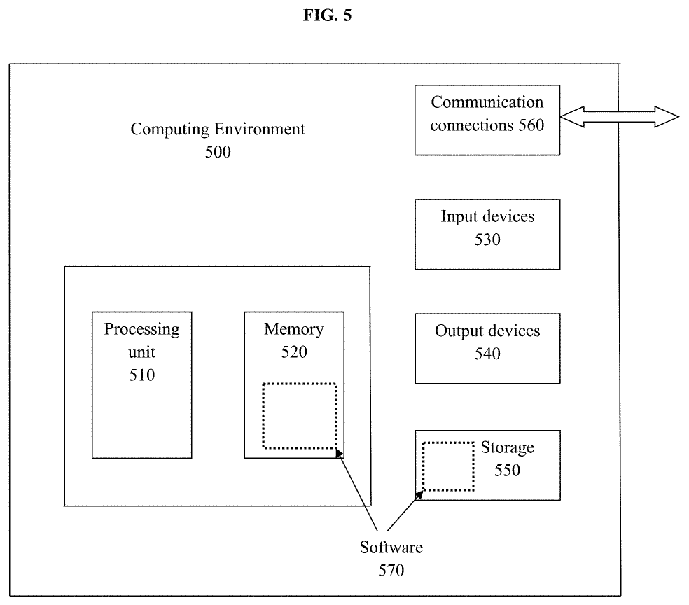

One or more of the above-described techniques may be implemented in or involve one or more computer systems. FIG. 5 illustrates a block diagram of a generalized computer network arrangement i.e. a system for compression and decompression in accordance with an embodiment of the present invention. FIG. 5 shows a generalized example of a computing environment 500. The computing environment 500 is not intended to suggest any limitation as to scope of use or functionality of described embodiments.

With reference to FIG. 5, the computing environment or system 500 includes at least one processing unit 510 and memory 520. The processing unit 510 may have single core and/or multi core for executing instructions. The processing unit 510 executes computer-executable instructions and may be a real or a virtual processor. In a multi-processing system, multiple processing units execute computer-executable instructions to increase processing power.

A system 500 for compression comprising: one or more processors; and one or more memory units operatively coupled to at least one of the one or more processors and having instructions stored thereon that, when executed by at least one of the one or more processors, cause at least one of the one or more processors to: read a numerical file, wherein the numerical file comprises a plurality of numerical elements; convert each numerical element into a 32-bit single precision floating point number such that a plurality of 32-bit single precision floating point numbers being generated corresponding to the plurality of numerical elements of the numerical file; combine said plurality of 32-bit single precision floating point numbers corresponding to the plurality of numerical elements of the numerical file such that a binary numerical file being generated; group the binary numerical file into a n-bit sequence pattern; the n-bit sequence pattern is an 8-bit sequence pattern or a 16-bit sequence pattern or a 32-bit sequence pattern or a 64-bit sequence pattern; generate a Huffman tree based on frequency of occurrences of a plurality of unique bit patterns present in the binary numerical file; generate a plurality of codewords corresponding to said plurality of unique bit patterns using said Huffman tree; a node of the Huffman tree is a unique bit pattern of said plurality of unique bit patterns; and replace said plurality of unique bit patterns present in the binary numerical file with the corresponding plurality of codewords such that a compressed binary numerical file being generated. A compression rate of said compressed binary numerical file is based on said n-bit sequence pattern.

A system 500 for decompression comprising: one or more processors; and one or more memory units operatively coupled to at least one of the one or more processors and having instructions stored thereon that, when executed by at least one of the one or more processors, cause at least one of the one or more processors to: read a compressed binary numerical file, wherein said compressed binary numerical file comprises a plurality of codewords; fetch a part of the compressed binary numerical file or the compressed binary numerical file using an address dictionary; and replace the plurality of codewords with a corresponding plurality of unique bit patterns by using a Huffman tree such that a decompressed binary numerical file being generated. The system 500 is further configured to generate an address dictionary, wherein the address dictionary comprises a plurality of addresses corresponding to a plurality of numerical elements of a numerical file.

The memory 520 may be volatile memory (e.g., registers, cache, RAM), non-volatile memory (e.g., ROM, EEPROM, flash memory, etc.), or some combination of the two. In some embodiments, the memory 520 stores software 570 implementing described techniques.

A computing environment may have additional features. For example, the computing environment 500 includes storage 550, one or more input devices 530, one or more output devices 540, and one or more communication connections 560. An interconnection mechanism (not shown) such as a bus, controller, or network interconnects the components of the computing environment 500. Typically, operating system software (not shown) provides an operating environment for other software executing in the computing environment 500, and coordinates activities of the components of the computing environment 500.

The storage 550 may be removable or non-removable, and includes magnetic disks, magnetic tapes or cassettes, CD ROMs, CD-RWs, DVDs, or any other medium which may be used to store information, and which may be accessed within the computing environment 500. In some embodiments, the storage 550 stores instructions for the software 570.

The input device(s) 530 may be a touch input device such as a keyboard, mouse, pen, trackball, touch screen, or game controller, a voice input device, a scanning device, a digital camera, or another device that provides input to the computing environment 500. The output device(s) 540 may be a display, printer, speaker, or another device that provides output from the computing environment 500.

The communication connection(s) 560 enable communication over a communication medium to another computing entity. The communication medium conveys information such as computer-executable instructions, audio or video information, or other data in a modulated data signal. A modulated data signal is a signal that has one or more of its characteristics set or changed in such a manner as to encode information in the signal. By way of example, and not limitation, communication media include wired or wireless techniques implemented with an electrical, optical, RF, infrared, acoustic, or other carrier.

Implementations may be described in the general context of computer-readable media. Computer-readable media are any available media that may be accessed within a computing environment. By way of example, and not limitation, within the computing environment 500, computer-readable media include memory 520, storage 550, communication media, and combinations of any of the above.

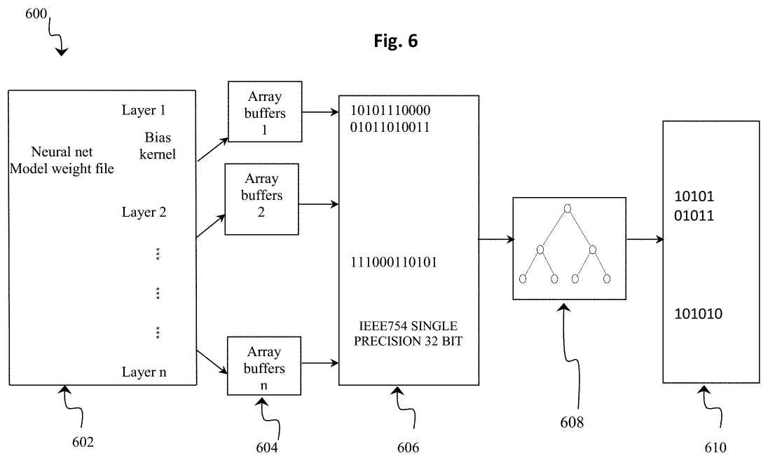

FIG. 6 illustrates a block diagram 600 of a compression technique applied in neural networks, in accordance with an embodiment of the present invention. At 602, each neural net model weight file contains multiple layers namely layer 1, layer 2, . . . layer n, representing the convolutional layers. Each layer consists of a combination of convolution, activation, pooling, normalization etc. Data in each layer constitutes of bias and kernel weights. At 604, there are multiple array buffers namely array buffers 1, array buffers 2, . . . array buffers n, wherein store the individual data components of each layer into the corresponding array buffers. At 606, The elements (real numbers) (i.e. numerical elements) of the individual array buffers are converted to IEEE 754 single precision 32-bit floating point. In other words, converted each numerical element into a 32-bit single precision floating point number. The said floating single precision bit values from all the layers of the entire neural net model are segregated into a file. In other words, combining the plurality of 32-bit single precision floating point numbers corresponding to the plurality of numerical elements associated with corresponding layers of the neural net model weight file such that a binary numerical file is generated. This file contains all bit values. So, direct Huffman implementation on this file would replace each bit value by a codeword whose length is greater than the single bit itself. To achieve this, create or generate a pattern of N bit sequences as a unique entity analogous to a symbol from which the Huffman tree is generated, where N=8, 16, 32, 64 (i.e. experimented separately with these patterns). For example, VGGNet model weights (single precision floating point representation) are grouped into 16-bit patterns. At 608, the frequency of repeatable patterns is then computed for constructing the Huffman tree i.e. generate a Huffman tree based on frequency of occurrences of a plurality of unique bit patterns present in the file. With the Huffman tree, generates the codewords for each node of the tree, representing each unique bit patterns. It means, each node of the Huffman tree represents a unique bit pattern of the plurality of unique bit patterns. At 610, each such unique bit pattern in the original file is replaced by the corresponding codewords to get the compressed binary file with different compression rates when executed on the individual patterns of different sizes of N

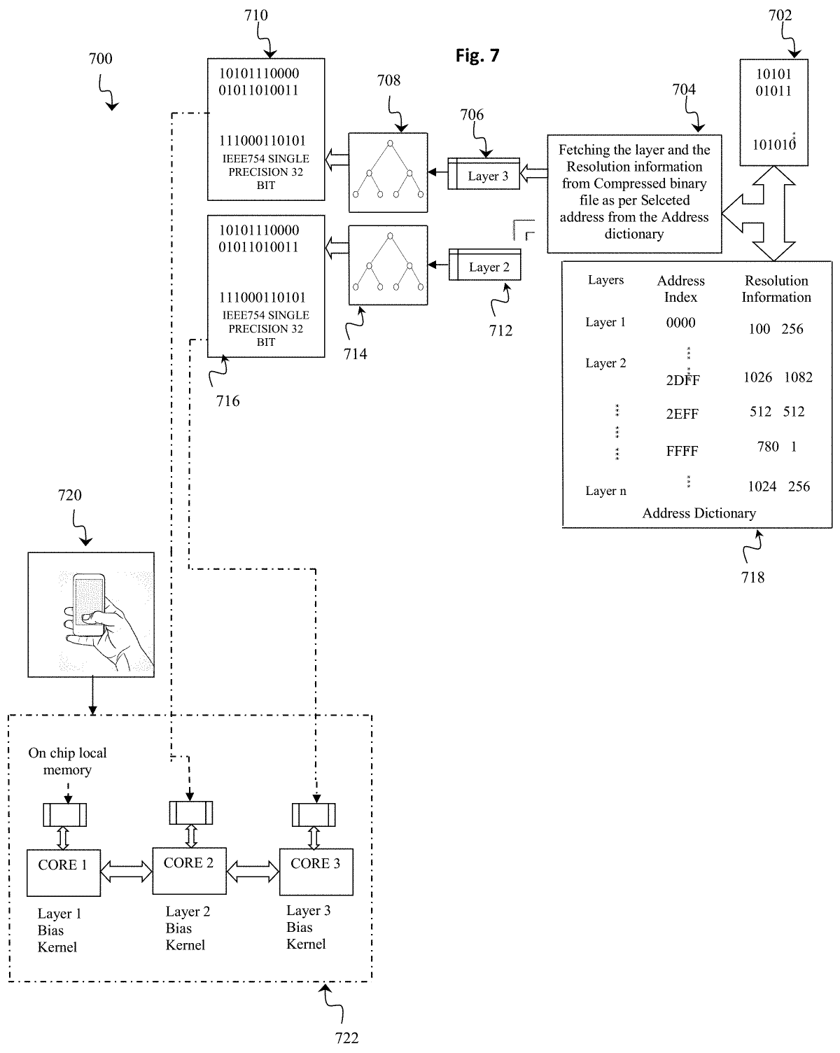

FIG. 7 illustrates a block diagram 700 of a decompression technique applied in neural networks, in accordance with an embodiment of the present invention. The compressed binary file generated in the compression stage is used as the input to the decompression stage. It means at 702, the compressed binary file is used as the input for decompression technique, wherein the compressed binary file comprises a plurality of codewords. At 718, after having compressed binary file as an input, an address dictionary is created which contains the starting address, offset of each layer/block (containing a single or multiple layers) of the neural network. The address dictionary also contains the data resolution information of the individual layers (bias, kernel weights etc.,). At 704, when the system demands to fetch a particular layer, it sends the beginning address information and the corresponding layer is fetched from the compressed binary file. At 706 and 712, layer 3 and layer 2 are fetched from the compressed binary file 702 using the address dictionary 718. Generally, the system may fetch the entire compressed binary file or part of the compressed binary file. Fetching a part of the compressed binary file means fetch a required layer or layers from the compressed binary file using the address dictionary 718. At 706 and 712, it is shown that the corresponding layers of the corresponding neural net model weight file are fetched. At 708, Huffman decoding algorithm is used or applied on the layer 3 to decompress the layer 3 and also at 714, Huffman decoding algorithm is used or applied on the layer 2 to decompress the layer 2. At 710, a decompressed file is generated using the Huffman Decoding algorithm where the weights are decoded in single precision 32-bit (IEEE 754) format corresponding to the layer 3. Similarly, at 716, a decompressed file is generated using the Huffman Decoding algorithm where the weights are decoded in single precision 32-bit (IEEE 754) format corresponding to the layer 2. In the similar manner, a decompressed binary file is generated by replacing the plurality of codewords with a corresponding plurality of unique bit patterns by using a Huffman tree such that a decompressed binary file is generated. At 720, neural net runs on a mobile device. At 722, it is envisaged that the layer wise information or even multiple layers forming a block can reside on the on-chip memory attached to a core on a multicore environment on an embedded mobile device.

The present invention is applied on four benchmark neural nets namely ResNet50, GoogLeNet(inception v3), Xception and AlexNet for experimental purpose.

TABLE 1

| | Bit pattern length | | | | | | | |
|---|---|---|---|---|---|---|---|---|
| | 8 bit | | 16 bit | | 32 bit | | 64 bit | |
| Neural | Compression | Decompression | Compression | Decompression | Compression | Decompression | Compression | Decompression |
| Nets | rate (%) | time (in secs) | rate (%) | time (in secs) | rate (%) | time (in secs) | rate (%) | time (in secs) |
| ResNet | 8 | 1.35 | 12 | 1.32 | 24.1 | 2.06 | 63 | 0.38 |
| GoogLeNet | 5 | 1.30 | 8.1 | 1.28 | 24 | 1.11 | 63.33 | 0.34 |
| (inception v3) | | | | | | | | |
| Xception | 7.5 | 1.26 | 11.4 | 1.23 | 23.4 | 1.09 | 63.34 | 0.33 |
| AlexNet | 8 | 2.05 | 12 | 1.15 | 23 | 1.06 | 61.1 | 0.35 |

Table 1 shows the compression rate and the single block decompression time of all the 8, 16, 32 and 64-bit pattern sequences respectively. It is to be noted that increasing the number of processing cores reducing the decompression time for the entire neural net model. In the present invention, four (4) core architecture is used for decompressing the neural net model. By applying the present invention on the existing neural nets, the compression rate varies based on different bit patterns. For 8-bit pattern, the compression rate varies from 5 to 8% approximately. For 16-bit pattern, the compression rate varies from 8 to 12% approximately. For 32-bit pattern, the compression rate varies from 23 to 24% approximately. For 64-bit pattern, the compression rate varies from 61 to 63% approximately. It is obvious that the compression rate is higher as the length of bit pattern grows, since large pattern can be replaced by codewords whose length is very small w.r.t to the pattern itself. Also, the time for single block decompression is provided correspondingly as shown in the Table 1. The decompression time depends on the search space (the dictionary, the codebook, the location of the nonzero values, etc.).

TABLE 2

| | 16-bit pattern (example) | | |
|---|---|---|---|
| | (10010 . . . 001) | (101001 . . . 11) | (11010 . . . 001) |
| Frequency | 15 | 8 | 32 |
| (in millions) | | | |
| Variable length | 1001 | 110111 | 101 |
| codeword | | | |

For example Table 2 shows an instance of the bit patterns and the frequency of occurrences of the bit patterns present in the file, wherein the file contains neural net model weights. This frequency information is used to create the Huffman tree. Once the tree is created the corresponding codewords for each node representing unique bit patterns is generated. It is to be noted from Table 2 that the least frequency of occurrences corresponds to the maximum length of codewords and vice versa.

The advantage of the decompression architecture as shown in the FIG. 7 is that multiple layers can be decompressed in parallel. The present invention is experimented with random fetching of the decompression layers and finally inserting back into the HDF5/model weight file with no loss of performance accuracy on ImageNet and COCO dataset. The software model has been designed to facilitate the hardware architecture to fetch randomly the layers into the local on chip memory (attached with the cores) as when the system demands as shown in the FIG. 7. The experimental results as shown in the Table 1 shows the compression rate of the present invention ranges from 29 to 63% approximately (for 32 and 64 bit patterns respectively) which is much better as compared to existing state-of-the-art results whose gain varies from 15 to 22% approximately with heterogeneous patterns without any loss of accuracy.

The present invention is provided with modified Huffman coding methodology which is applied directly on the binary equivalent of the unprocessed network weights. Analyzed with multiple bit patterns from different neural nets (namely ResNet, GoogLeNet, Xception and AlexNet) achieving a maximum network compression of about 64% and a least single layer decompression time of about 0.33 seconds. Moreover, generated an address dictionary which is used to fetch and decode from the compressed file at random in parallel to fetch parts of a compressed file, decompress and place into on chip local cache memories attached to individual cores of a multicore mobile device. This can be done without halting the ongoing working process of other memory-core modules and necessitating the need and requirement to place the entire decompressed file on a single on chip memory component which is even not suggestible with the limitations of handheld portable device.

Having described and illustrated the principles of the invention with reference to described embodiments, it will be recognized that the described embodiments may be modified in arrangement and detail without departing from such principles.

In view of the many possible embodiments to which the principles of the invention may be applied, we claim the invention as all such embodiments may come within the scope and spirit of the claims and equivalents thereto.

While the present invention has been related in terms of the foregoing embodiments, those skilled in the art will recognize that the invention is not limited to the embodiments depicted. The present invention may be practiced with modification and alteration within the spirit and scope of the appended claims. Thus, the description is to be regarded as illustrative instead of restrictive on the present invention.

The detailed description is presented to enable a person of ordinary skill in the art to make and use the invention and is provided in the context of the requirement for obtaining a patent. The present description is the best presently-contemplated method for carrying out the present invention. Various modifications to the preferred embodiment will be readily apparent to those skilled in the art and the generic principles of the present invention may be applied to other embodiments, and some features of the present invention may be used without the corresponding use of other features. Accordingly, the present invention is not intended to be limited to the embodiment shown but is to be accorded the widest scope consistent with the principles and features described herein.

We claim:

1. A method for compression, the method comprising:
reading a numerical file, wherein the numerical file comprises a plurality of numerical elements;
converting each numerical element into a 32-bit single precision floating point number such that a plurality of 32-bit single precision floating point numbers being generated corresponding to the plurality of numerical elements of the numerical file;
combining the plurality of 32-bit single precision floating point numbers corresponding to the plurality of numerical elements of the numerical file such that a binary numerical file being generated;
grouping the binary numerical file into a n-bit sequence pattern;
generating a Huffman tree based on frequency of occurrences of a plurality of unique bit patterns present in the binary numerical file;
generating a plurality of codewords corresponding to the plurality of unique bit patterns using the Huffman tree; and
replacing the plurality of unique bit patterns present in the binary numerical file with the corresponding plurality of codewords such that a compressed binary numerical file being generated.

2. The method of claim 1, wherein a node of the Huffman tree is a unique bit pattern of the plurality of unique bit patterns.

3. The method of claim 1, wherein a compression rate of the compressed binary numerical file is based on the n-bit sequence pattern, wherein the n-bit sequence pattern is at least one of: an 8-bit sequence pattern, a 16-bit sequence pattern, a 32-bit sequence pattern or a 64-bit sequence pattern.

4. A method for decompression, the method comprising:
reading a compressed binary numerical file, wherein the compressed binary numerical file comprises a plurality of codewords;
fetching a part of the compressed binary numerical file or the compressed binary numerical file using an address dictionary; and
replacing the plurality of codewords with a corresponding plurality of unique bit patterns by using a Huffman tree such that a decompressed binary numerical file being generated.

5. The method of claim 4 further comprising: generating an address dictionary, wherein the address dictionary comprises a plurality of addresses corresponding to a plurality of numerical elements of a numerical file.

6. The method of claim 4, wherein the compressed binary numerical file is generated by replacing the plurality of unique bit patterns present in a binary numerical file with the corresponding plurality of codewords.

7. The method of claim 4, wherein the Huffman tree is generated based on frequency of occurrences of the plurality of unique bit patterns present in the binary numerical file.

8. The method of claim 4, wherein a node of the Huffman tree is a unique bit pattern of the plurality of unique bit patterns.

9. The method of claim 6, wherein the binary numerical file is grouped into a n-bit sequence pattern, wherein the n-bit sequence pattern is at least one of: an 8-bit sequence pattern, a 16-bit sequence pattern, a 32-bit sequence pattern or a 64-bit sequence pattern.

10. The method of claim 6, wherein the binary numerical file is generated by combining a plurality of 32-bit single precision floating point numbers corresponding to the plurality of numerical elements of the numerical file.

11. The method of claim 4, wherein a decompression time of the decompressed binary numerical file is based on the n-bit sequence pattern, wherein the n-bit sequence pattern is at least one of: an 8-bit sequence pattern, a 16-bit sequence pattern, a 32-bit sequence pattern or a 64-bit sequence pattern.

12. An apparatus for compression, the apparatus comprising:
a processor;
a memory operatively coupled to the processor for executing a plurality of modules present in the memory, the plurality of modules comprising:
a read module configured to read a numerical file, wherein the numerical file comprises a plurality of numerical elements;
a conversion module configured to convert each numerical element into a 32-bit single precision floating point number such that a plurality of 32-bit single precision floating point numbers being generated corresponding to the plurality of numerical elements of the numerical file;
a combination module configured to combine the plurality of 32-bit single precision floating point numbers corresponding to the plurality of numerical elements of the numerical file;
a binary numerical file generation module configured to generate a binary numerical file by combining the plurality of 32-bit single precision floating point numbers corresponding to the plurality of numerical elements of the numerical file;
a group module configured to group the binary numerical file into a n-bit sequence pattern;
a Huffman tree generation module configured to generate a Huffman tree based on frequency of occurrences of a plurality of unique bit patterns present in the binary numerical file;
a codeword generation module configured to generate a plurality of codewords corresponding to the plurality of unique bit patterns using the Huffman tree;
a replaceable module configured to replace the plurality of unique bit patterns present in the binary numerical file with the corresponding plurality of codewords; and
a compressed binary numerical file generation module configured to generate a compressed binary numerical file by replacing the plurality of unique bit patterns present in the binary numerical file with the corresponding plurality of codewords.

13. The apparatus of claim 12, wherein a node of the Huffman tree is a unique bit pattern of the plurality of unique bit patterns.

14. The apparatus of claim 12, wherein a compression rate of the compressed binary numerical file is based on the n-bit sequence pattern, wherein the n-bit sequence pattern is at least one of: an 8-bit sequence pattern, a 16-bit sequence pattern, a 32-bit sequence pattern or a 64-bit sequence pattern.

15. An apparatus for decompression, the apparatus comprising:
a processor;
a memory operatively coupled to the processor for executing a plurality of modules present in the memory, the plurality of modules comprising:
a read module configured to read a compressed binary numerical file, wherein the compressed binary numerical file comprises a plurality of codewords;
a fetch module configured to fetch a part of the compressed binary numerical file or the compressed binary numerical file using an address dictionary;
a replaceable module configured to replace the plurality of codewords with a corresponding plurality of unique bit patterns by using a Huffman tree; and
a decompressed binary numerical file generation module configured to generate a decompressed binary numerical file by replacing the plurality of codewords with the corresponding plurality of unique bit patterns by using the Huffman tree.

16. The apparatus of claim 15 further comprising: an address dictionary module configured to generate an address dictionary, wherein the address dictionary comprises a plurality of addresses corresponding to a plurality of numerical elements of a numerical file.

17. The apparatus of claim 15, wherein a compressed binary numerical file generation module is configured to generate the compressed binary numerical file by replacing the plurality of unique bit patterns present in a binary numerical file with the corresponding plurality of codewords.

18. The apparatus of claim 15, wherein a Huffman tree generation module is configured to generate the Huffman tree based on frequency of occurrences of the plurality of unique bit patterns present in the binary numerical file.

19. The apparatus of claim 15, wherein a node of the Huffman tree is a unique bit pattern of the plurality of unique bit patterns.

20. The apparatus of claim 17, wherein the binary numerical file is grouped into a n-bit sequence pattern, wherein the n-bit sequence pattern is at least one of: an 8-bit sequence pattern, a 16-bit sequence pattern, a 32-bit sequence pattern or a 64-bit sequence pattern.

21. The apparatus of claim 17, wherein a binary numerical file generation module is configured to generate a binary numerical file by combining a plurality of 32-bit single precision floating point numbers corresponding to the plurality of numerical elements of the numerical file.

22. The apparatus of claim 15, wherein a decompression time of the decompressed binary numerical file is based on the n-bit sequence pattern, wherein the n-bit sequence pattern is at least one of: an 8-bit sequence pattern, a 16-bit sequence pattern, a 32-bit sequence pattern or a 64-bit sequence pattern.
